(19) United States
(12) Patent Application Publication
(10) Pub. No.: US 2008/0237634 A1
(43) Pub. Date: Oct. 2, 2008

(54) CRYSTALLOGRAPHIC RECESS ETCH FOR EMBEDDED SEMICONDUCTOR REGION

(75) Inventors: Thomas W. Dyer, Pleasant Valley, NY (US); Dureseti Chidambarrao, Weston, CT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/693,792

(22) Filed: Mar. 30, 2007

(51) Int. Cl. H01L 29/78

(52) U.S. Cl. 257/190

(57) ABSTRACT

Source and drain regions of an FET are etched by a crystallographic anisotropic etch to form a cavity surrounded by crystallographic facets. The exposure of the sidewalls of shallow trench isolation (STI) is avoided or reduced compared to the prior art. The crystallographic anisotropic etch may be combined with an isotropic etch or a recess etch to create undercuts beneath gate spacers and/or a pegging line beneath a top surface of the STI. The at least one cavity is then filled with a lattice-mismatched embedded material so that stress is applied to the channel of the FET. The resulting structure has increased containment of the embedded semiconductor region by shallow trench isolation. A reduction in stress due to the unconstrained sidewall area and an increase in the junction current due to the recessing of the pegging line are eliminated or alleviated.

### FIELD OF THE INVENTION

The present invention relates to semiconductor structures, and particularly, to semiconductor structures with at least one embedded semiconductor region and methods of manufacturing the same.

### BACKGROUND OF THE INVENTION

Stress in the channel of a field effect transistor (FET) affects the on-current by altering the band structure of the semiconductor material, and consequently, the mobility of charge carriers. For example, the hole mobility of a p-type FET formed on a silicon substrate increases under a uniaxial compressive stress in the direction of the channel, i.e., along a line connecting the source and the drain. Similarly, the electron mobility of an n-type FET formed on a silicon substrate increases under a uniaxial tensile stress in the direction of the channel. The change in the mobility of minority carriers depends on the type and direction of stress as well as the semiconductor substrate material. By manipulating stress on the channel of an FET, the performance of the FET may be enhanced.

One method for generating stress in the channel of an FET is to embed a stress-generating material within portions of an active area of a semiconductor substrate. The embedded portions of the active area are typically source and drain regions of the FET so that stress may be applied to the channel. The embedded material is epitaxially grown on the underlying semiconductor substrate material with a forced match in the lattice constant with resulting strain in the embedded semiconductor region. The strained embedded semiconductor region applies either tensile or compressive stress on the surrounding semiconductor structures. Therefore, by embedding the source and drain regions of a FET with a lattice mismatched semiconductor material relative to the underlying substrate semiconductor material, carrier mobility in the channel, and consequently, the device on-current may be increased in the FET.

To successfully generate stress in the channel of a FET, the embedded material needs to be epitaxially grown on the underlying substrate semiconductor material. Therefore, the embedded semiconductor region has the same crystalline structure as and a small lattice mismatch, typically less about than 10%, and preferably less than 3%, relative to the underlying substrate semiconductor material. The choice of embedded semiconductor material depends on the substrate semiconductor material, the type of semiconductor device, and the geometry of the embedded region. For example, if the source and drain regions of a p-type insulated gate field effect transistor (IGFET) on a silicon substrate is to be embedded with a compressive-stress-generating material, a silicon germanium alloy may be employed. Similarly, a carbon doped silicon may be employed within the source and drain regions of an n-type IGFET on a silicon substrate to generate a tensile stress on the channel.

In general, a selective epitaxy process deposits a semiconductor material on a semiconductor surface while suppressing the deposition of the semiconductor material on a dielectric surface. This is achieved by introducing reactants and etchants into a process chamber at the same time so that an etching process competes with the deposition process. On a semiconductor surface, a rapid deposition of the semiconductor material occurs as semiconductor atoms from the reactant molecules diffuse on the surface to be incorporated into ledges, which has a high number of available bonds and located on the semiconductor surface. Thus, the semiconductor surface grows ledge by ledge and layer by layer. The deposition rate exceeds the etch rate on the semiconductor surface and a net deposition occurs. On the dielectric surface, however, semiconductor ledges are not present. For any deposition of a semiconductor material to occur, therefore, the semiconductor material must nucleate first. Since the nucleation may occur only if the semiconductor atoms from the reactant molecules form bonds on the dielectric surface, the nucleation rate is lower than the deposition rate. In a selective epitaxy process, the nucleation rate is lower than the etch rate, and no deposition of the semiconductor material occurs on the surface of the dielectric material.

In general, ledges play a key role in an epitaxy process by providing sites at which semiconductor atoms that originate from the reactants and diffuse on the surface can be incorporated into the semiconductor surface. Depending on the orientation of the surface, the number of available bonds at a ledge varies for a given semiconductor material. Therefore, the rate of growth in an epitaxy process is often anisotropic, i.e., different along different crystallographic orientations, often causing facets on the semiconductor surface as a result. In a selective epitaxy process, the anisotropy in the net deposition rate is magnified over the anisotropy of the deposition rate from the reactants, since the net deposition rate is equal to the anisotropic deposition rate less the etch rate, which tends to be isotropic.

Referring to FIG. 1, an exemplary prior art structure with embedded stress-generating semiconductor material formed by selective epitaxy is shown. The gate of an insulated gate field effect transistor (IGFET) comprises a gate dielectric 30 formed on a substrate semiconductor region 10, a gate semiconductor 32, a gate cap insulator 34, an L-shaped first gate spacer 40, and a second spacer 42. Embedded semiconductor regions 12 are formed by recessing portions of the semiconductor substrate 2 by a reactive ion etch and selectively depositing an embedded semiconductor material. Source and drain regions (not shown explicitly) of the IGFET comprises portions of the embedded semiconductor regions 12. The substrate semiconductor region 10 is a (001) silicon crystal region. The source and drain regions 12 are filled with a silicon germanium alloy, and are bounded by shallow trench isolation (STI) 20, which comprises a dielectric material such as silicon oxide.

In this case, the growth rate of the silicon germanium alloy is high in the [001] orientations but is close to zero in the [111] orientations. Therefore, during a selective epitaxy process, the (001) surfaces 13 move upward in the <001> orientation as the embedded semiconductor region grows while the {111} surfaces 15 do not grow in the [111] orientations and grows only laterally. The growth of the embedded semiconductor region 12 is pegged at the pegging line P on the surface of the STI 20 since the embedded semiconductor region 12 does not grow along sidewalls of the STI 20.

The absence of the embedded semiconductor material above the pegging line P has an adverse impact on the FET performance. Since the {111} surfaces 15 are not confined by the STI 20 in this configuration, the epitaxial strain caused by the lattice mismatch between the embedded semiconductor region 12 in the source and drain regions and the substrate semiconductor region 10 is partially relieved by deformation of the {111} surfaces 13, i.e., their movement away from the channel. Thus, the stress at the channel of the IGFET is reduced by the unconfined semiconductor surfaces below a top surface of the STI 20. Further, junction depth increases by the depth of the pegging line P near the STI after the source and drain ion implantation, which may cause junction leakage current to increases by orders of magnitude.

While FIG. 1 demonstrates an example of reduction of stress for a particular combination of substrate semiconductor material, embedded semiconductor material, and surface orientations, in general, differences in the growth rate of the embedded semiconductor region along different crystallographic orientations can cause a pegging line on shallow trench isolation above which the embedded semiconductor region does not grow. Such an absence of contact between an embedded semiconductor region and shallow trench isolation above a pegging line provides a strain relaxation mechanism for the embedded semiconductor region, thereby causing a reduction of stress in the channel.

Therefore, there exists a need for a semiconductor structure with an embedded semiconductor region that provides containment of embedded semiconductor region with sidewalls of shallow trench isolation, and thus, alleviates stress reduction and/or junction leakage current increase, and methods of manufacturing the same.

### SUMMARY OF THE INVENTION

The present invention addresses the needs described above by providing semiconductor structures having an embedded semiconductor region with increased constraint by shallow trench isolation and methods of manufacturing the same.

Specifically, source and drain regions of an FET are etched by a crystallographic anisotropic etch to form at least one cavity surrounded by crystallographic facets. The exposure of the sidewalls of shallow trench isolation (STI) is eliminated or reduced compared to the prior art. The crystallographic anisotropic etch may be combined with an isotropic etch or a recess etch to create undercuts beneath gate spacers and/or a pegging line beneath a top surface of the STI. The at least one cavity is then filled with a lattice-mismatched embedded material so that stress is applied to the channel of the FET. The embedded semiconductor region may adjoin a top surface of the STI. Alternatively, a pegging line P, above which the embedded semiconductor region does not contact the STI, may be formed on the shallow trench isolation. The resulting structure has increased containment of the embedded semiconductor region by shallow trench isolation. A reduction in stress due to the unconstrained sidewall area and an increase in the junction current due to the recessing of the pegging line P are eliminated or alleviated.

According to the present invention, a semiconductor structure contains:

a substrate semiconductor region comprising a substrate semiconductor material and located within a semiconductor substrate;

at least one embedded semiconductor region comprising an embedded semiconductor material and located within the semiconductor substrate, wherein the embedded semiconductor material and the semiconductor substrate material have different material compositions; and

at least one boundary where at least two first facets of the substrate semiconductor region adjoin at least two second facets of the at least one embedded semiconductor region, wherein adjoined facets across the boundary have the same crystallographic orientation, and the first facets and the second facets are adjoined by a ridge.

Preferably, a vertical cross-section perpendicular to the ridge is a polygon having at least three sides, wherein at least three surfaces of the embedded semiconductor region containing the at least three sides of the polygon are major crystallographic surfaces with low Miller indices. The major crystallographic surfaces may be selected from a group consisting of {100}, {110}, {111}, {211}, {221}, {311}, {321}, {331}, and {332}.

In one embodiment, the polygon may have at least four sides, and three surfaces of the embedded semiconductor region containing three of the at least four sides may directly contact the substrate semiconductor region with epitaxial alignment. The polygon may be a trapezoid. Two surfaces of the embedded semiconductor region containing two parallel sides of the four sides of the polygon may comprise a set of two facets having the same orientation as the semiconductor substrate.

In another embodiment, the polygon may have at least five sides, and at least three surfaces of the embedded semiconductor region containing at least three of the at least five sides may directly contact the substrate semiconductor region with epitaxial alignment. The polygon may be a pentagon. A surface of the embedded semiconductor region not adjoining the substrate semiconductor region may comprise a facet having the same orientation as the semiconductor substrate.

In still another embodiment, the polygon may have at least six sides, and at least five surfaces of the embedded semiconductor region containing at least five of the at least six sides may directly contact the substrate semiconductor region with epitaxial alignment. The polygon may be a hexagon. Two surfaces of the embedded semiconductor region containing two of the six sides of the polygon may comprise a set of two facets having the same orientation as the semiconductor substrate.

In yet another embodiment, the polygon may have at least three sides, and at least two surfaces of the embedded semiconductor region containing at least two of the at least three sides may directly contact the substrate semiconductor region with epitaxial alignment. The polygon may be a triangle. One surface of the embedded semiconductor region containing one of the three sides of the polygon may comprise a facet having the same orientation as the semiconductor substrate.

The semiconductor substrate may have any crystallographic orientation. For example, the semiconductor substrate may be a (001) orientation substrate. The facets are crystallographic planes with low Miller indices with none of the indices exceeding 6 in magnitude. For example, at least three surfaces of the embedded semiconductor region containing the three sides may comprise a (001) facet and a set of two {110} facets.

The embedded semiconductor region may abut a bottom surface of a gate spacer of an insulated gate field effect transistor (IGFET).

The substrate semiconductor material and the embedded semiconductor material may have the same crystal structure and a lattice mismatch in the range from 0% to about 10%.

An edge of the at least one embedded semiconductor region may adjoin a top surface of shallow trench isolation. Alternatively, a surface of the at least one embedded semiconductor region may adjoin a sidewall surface of shallow trench isolation.

According to another aspect of the present invention, a method of manufacturing a semiconductor structure, comprises:

providing a semiconductor substrate having a substrate semiconductor region and at least one exposed semiconductor surface;

subjecting the at least one exposed semiconductor surface to a crystallographic anisotropic etch;

forming at least one cavity with crystallographic facets within the semiconductor substrate; and

forming at least one embedded semiconductor region by filling the at least one cavity with an embedded semiconductor material, wherein the embedded semiconductor material is epitaxially aligned with the substrate semiconductor material.

The method may further comprise recessing the at least one exposed semiconductor surface with a reactive ion etch prior to forming the at least one cavity.

The method may further comprise performing an isotropic etch on the at least one cavity of the semiconductor substrate.

A bottom surface of a spacer of an insulated gate field effect transistor (IGFET) may be exposed.

Preferably, the embedded semiconductor region and the substrate semiconductor region have different material compositions and the embedded semiconductor region applies stress to the substrate semiconductor region.

The method may further comprise forming at least one boundary where at least two first facets of the substrate semiconductor region adjoin at least two second facets of the at least one embedded semiconductor region, wherein adjoined facets across the boundary have the same crystallographic orientation, and the first facets and the second facets are adjoined by a ridge.

A vertical cross-section perpendicular to the ridge may be a polygon selected from a group comprising a triangle, a trapezoid, a pentagon, and a hexagon with at least three sides, wherein surfaces of the embedded semiconductor region containing the at least three sides of the polygon are major crystallographic surfaces with low Miller indices. The major crystallographic surfaces may be selected from a group consisting of {100}, {110}, {111}, {211}, {221}, {311}, {321}, {331}, and {332}.

The semiconductor substrate may be a (001) orientation silicon substrate and the surfaces of the embedded semiconductor region may comprise at least one (001) surface and at least two {111} surfaces.

### BRIEF DESCRIPTION OF THE DRAWINGS

FIG. 1 is a vertical cross-sectional view of an exemplary prior art structure containing embedded semiconductor regions and {111} facets in a (001) silicon substrate.

FIGS. 2-5 are sequential cross-sectional views of a first exemplary semiconductor structure with embedded semiconductor regions according to a first embodiment of the present invention.

FIGS. 6-8 are sequential cross-sectional views of a second exemplary semiconductor structure with embedded semiconductor regions according to a second embodiment of the present invention.

FIGS. 9-11 are sequential cross-sectional views of a third exemplary semiconductor structure with embedded semiconductor regions according to a third embodiment of the present invention.

FIGS. 12-16 are sequential cross-sectional views of a fourth exemplary semiconductor structure with embedded semiconductor regions according to a fourth embodiment of the present invention.

FIGS. 17-19 are sequential cross-sectional views of a fifth exemplary semiconductor structure with embedded semiconductor regions according to a fifth embodiment of the present invention.

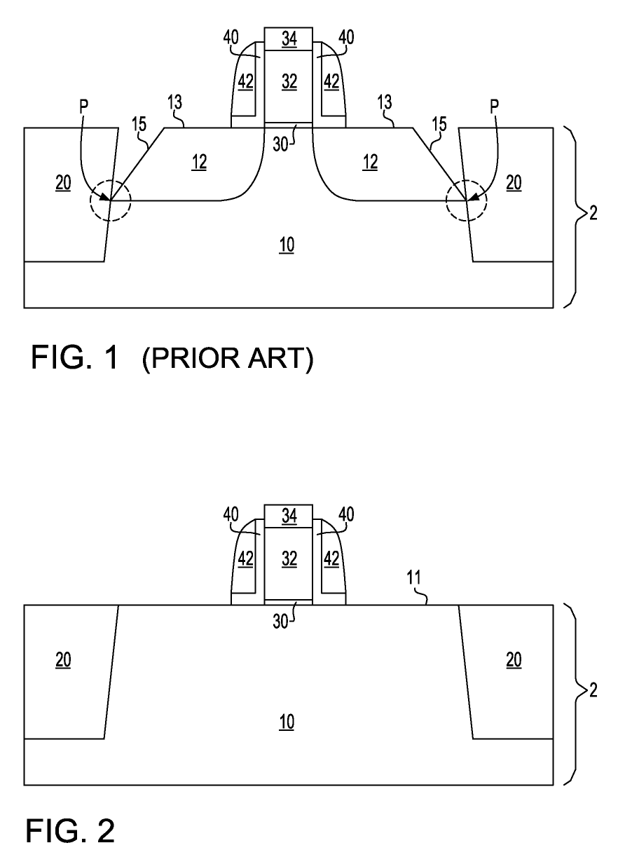

### DETAILED DESCRIPTION OF THE INVENTION

As stated above, the present invention relates to semiconductor structures with an embedded semiconductor region and methods of manufacturing the same, which are now described in detail with accompanying figures. It is noted that like and corresponding elements are referred to by like reference numerals.

Referring to FIG. 2, a first exemplary semiconductor structure according to the present invention comprises a semiconductor substrate 2 that contains a substrate semiconductor region 10 and shallow trench isolation 20. A gate of an insulated gate field effect transistor (IGFET) comprises a gate dielectric 30 located on the substrate semiconductor region 10, a gate semiconductor 32, a gate cap insulator 34, an L-shaped first gate spacer 40, and a second spacer 42. Exposed portions of an original semiconductor surface 11 include the area between the gate and the shallow trench isolation 20.

The semiconductor materials in the substrate semiconductor region 10 comprises a semiconductor material such as silicon, germanium, silicon-germanium alloy, silicon-carbon alloy, and silicon-germanium-carbon alloy, gallium arsenide, indium arsenide, indium phosphide, III-V compound semiconductor materials, II-VI compound semiconductor materials, organic semiconductor materials, and other compound semiconductor materials.

The semiconductor substrate 2 may be a bulk substrate, a semiconductor-on-insulator (SOI) substrate, or a hybrid substrate. The orientation of the semiconductor substrate 2 is determined by the crystallographic orientation of the substrate semiconductor region 10 underneath the gate structure along a surface normal of the semiconductor substrate 2. An SOI substrate or a hybrid substrate may have multiple regions of semiconductor material with different crystallographic orientations in the same semiconductor substrate. In this case, the orientation of the semiconductor substrate 2 is defined locally by the orientation of the substrate semiconductor region 10 underneath a semiconductor device in reference.

The L-shaped first spacer 40 and the second spacer 42 may be replaced with other types of spacers, or even eliminated in the practice of the present invention. Further, any semiconductor structure with at least one patterned exposed semiconductor surface may be employed to form embedded semiconductor regions in the practice of the present invention. The IGFETs in the first and subsequent exemplary structures, do not limit the application of the present invention to semiconductor structures containing an IGFET in any way, but serves as a demonstration of the practicability of the present invention.

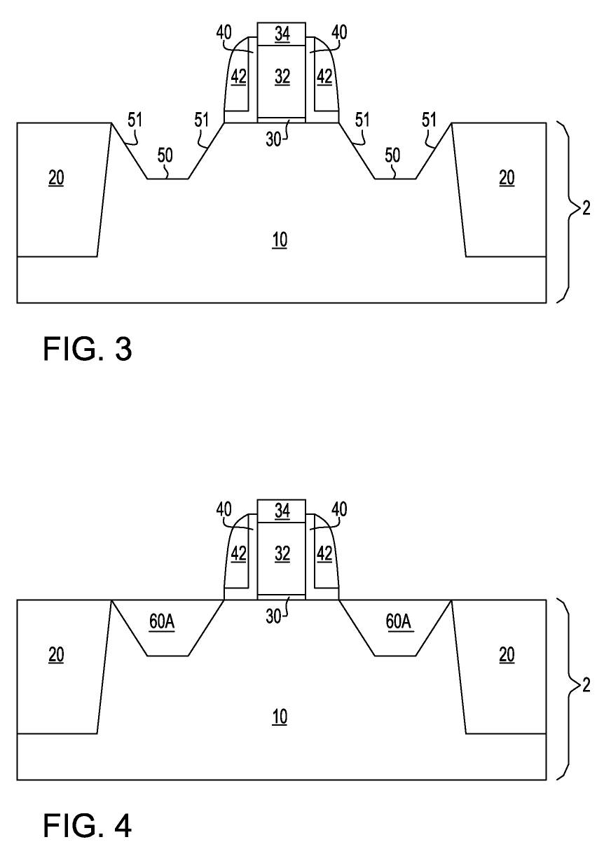

Referring to FIG. 3, the at least one exposed original semiconductor surface 11 (shown in FIG. 2), which is the source and drain regions of the IGFET in the first exemplary semiconductor structure, is subjected to a crystallographic anisotropic etch. The substrate semiconductor material in the substrate semiconductor region 10 is etched at different etch rates along different crystallographic orientations with a high degree of anisotropy. The crystallographic anisotropic etch forms at least one cavity surrounded by outer walls made of crystallographic facets.

The crystallographic anisotropic etch may employ a wet etch process or a reactive ion etch process. Both types of crystallographic anisotropic etch processes need to have anisotropic etch rates along different crystallographic orientations of the substrate. A high etch rate crystallographic facet, which has a high etch rate for a given crystallographic anisotropic etch, moves rapidly in the direction normal to the facet. Conversely, a low etch rate crystallographic facet, which has a low etch rate for a given crystallographic anisotropic etch, moves slowly in the direction normal to the facet. It is noted that “high” or “low” etch rates are relative to each other i.e., measured against etch rates along different orientations of the same material in a given etch process. The ratio of the etch rates between the high etch rate crystallographic facet and the etch rate crystallographic facet is about 3 or greater, and preferably about 10 or greater, and more preferably about 30 or greater. Oftentimes, the area of a low etch rate crystallographic facet may increase as a high etch rate crystallographic facet slides along the surface of the low etch rate crystallographic facet. A prolonged crystallographic anisotropic etch tends to form predominantly low etch rate crystallographic facets in a resulting structure, while a prematurely terminated crystallographic anisotropic etch tends to form both high etch rate crystallographic facets and low etch rate crystallographic facets.

FIG. 3 shows both high etch rate crystallographic facets 50 and low etch rate crystallographic facets 51 formed in the semiconductor substrate 2 by the crystallographic anisotropic etch of the substrate semiconductor region 10. The substrate semiconductor material is not etched from the sidewalls of the shallow trench isolation 20 since a low etch rate crystallographic facet 51 is formed from the interface between the original exposed semiconductor surface 11 and the shallow trench isolation 20 and extends downward at an angle less than 90 degrees relative to the original exposed semiconductor surface 11.

For example, the semiconductor substrate 2 may be a silicon substrate. In this case, the following exemplary crystallographic anisotropic etch processes may be used to form low etch rate crystallographic facets having {110} orientations on a silicon substrate. A first example of such a process is a wet etch process utilizing a pure TMAH (tetramethyl-ammonium hydroxide; (CH₃) ₄NOH) solution, which produces {110} facets due to a low etch rate perpendicular to {110} facets. A second example is a wet etch process which comprises a pretreatment with SCI clean consisting of a mixture of H₂O, NH₄OH, and H₂O₂, followed by an etch in a dilute hydrofluoric acid (DHF), then followed by another etch in an ammonium hydroxide solution (NH₄OH). This process also has a low etch rate perpendicular to {110} facets compared to other facets. A third example is a reactive ion etch used for deep trench formation in the DRAM processes, which tends to produce {110} facets on the surface of the semiconductor material.

Alternatively, the following exemplary crystallographic anisotropic etch process may be used to form low etch rate crystallographic facets having {100} orientations on a silicon substrate. The exemplary crystallographic anisotropic etch process comprises a pretreatment in a dilute hydrofluoric acid (DHF), followed by drying in an environment containing isopropyl alcohol (IPA) vapor, then followed by an etch in an ammonium hydroxide (NH₄OH) solution.

In general, for an arbitrary substrate semiconductor material, a wet etch process or a reactive ion etch processes may be employed as a crystallographic anisotropic etch as long as the etchant has an anisotropic etch rate along different crystallographic planes. In the case of an anisotropic wet etch process, the semiconductor substrate may be pretreated with a chemical that modifies the ratio of etch rates along different crystallographic planes of the semiconductor substrate prior to subjecting the exposed semiconductor surface to the etchant.

Preferably, the crystallographic facets are major crystallographic surfaces with low Miller indices such as {100}, {110}, {111}, {211}, {221}, {311}, {321}, {331}, and {332}. In general, if none of the indices have numbers exceeds 6 in magnitude, the corresponding crystallographic surface may be considered a major crystallographic surface with low Miller indices. The angle between a surface normal of some of the crystallographic facets and a surface normal of common semiconductor substrate orientations are tabulated in Table 1.

TABLE 1
Angles between a surface normal of common semiconductor substrate
orientations and a surface normal of some of the crystallographic facets

| | {100} | {110} | {111} | {211} | {221} | {311} |
|---|---|---|---|---|---|---|
| | facets | facets | facets | facets | facets | facets |
| Substrate | 0 degree | 45 degrees | ~54.73 degrees | ~35.26 or | ~48.18 or | ~25.24 or |
| orientation | | | | ~65.90 | ~70.53 | ~72.45 |
| (100) | | | | degrees | degrees | degrees |
| Substrate | 45 degrees | 0 degree | ~35.26 degrees | ~30.01, | ~19.47, 45 | ~31.48 or |
| orientation | | | | ~54.74 or | or ~76.36 | ~64.76 |
| (110) | | | | ~73.22 | degrees | degrees |
| | | | | degrees | | |
| Substrate | ~54.73 degrees | ~35.26 degrees | 0 degree | ~19.47 or | ~15.79, | ~29.49, |
| orientation | | | | ~61.87 | ~54.74 or | ~58.52 or |
| (111) | | | | degrees | ~78.90 | ~79.98 |
| | | | | | degrees | degrees |

The angle between the surface normal of the crystallographic facets and the substrate orientation is less than 90 degrees. Typically, a pair of low etch rate crystallographic facets 51 are formed in the semiconductor substrate 2 as well as a high etch rate crystallographic facet 50 in each cavity. If the crystallographic anisotropic etch is terminated before the high etch rate crystallographic facet is reduced to a ridge, the exemplary structure in FIG. 3 is formed. Preferably, the high etch rate crystallographic facets 50 are parallel to the original semiconductor surface 11. Alternatively, the high etch rate crystallographic facet 50 may not be parallel to the original semiconductor surface 11. While the angle between facets may vary depending on the substrate orientation and the crystallographic etch process, a ridge is formed where two facets are adjoined to each other. Thus, the crystallographic anisotropic etch produces at least one cavity surrounded by crystallographic facets adjoined by two ridges on the substrate semiconductor region 10.

Referring to FIG. 4, an embedded semiconductor material is deposited on the facets (50, 51) of the substrate semiconductor region 10 preferably by selective epitaxy. Preferably, the embedded semiconductor material has a different composition than the substrate semiconductor material in the substrate semiconductor region 10. Preferably, the embedded semiconductor material has the same crystal structure as the substrate semiconductor material and has a lattice mismatch in the range from 0% to about 10%, and preferably from 0% to about 3%. Preferably, the selective epitaxy process provides a higher growth rate to surfaces that are parallel to the original semiconductor surface 11 than to surfaces that are parallel to the low etch rate crystallographic facets 51. In other words, the selective epitaxy causes the embedded semiconductor material to grow at a higher growth rate from surfaces that are parallel to the original semiconductor surface 11 in the direction perpendicular to the original semiconductor surface 11 than the growth rate of the embedded semiconductor material from the low etch rate crystallographic facet 51 in the direction perpendicular to the low etch rate crystallographic facets 51. This causes the growth surface of the embedded semiconductor material to be parallel to the high etch rate crystallographic facet 50. The embedded semiconductor material thus forms trapezoidal embedded semiconductor regions 60A, i.e., embedded semiconductor regions with a trapezoidal cross-sectional area.

The epitaxial constraint, i.e., the forced alignment of the atoms of the embedded semiconductor material with the underlying crystal structure of the substrate semiconductor region 10, causes the embedded semiconductor material to be strained. The strained embedded semiconductor region 60A exerts stress on neighboring semiconductor structures, including the channel of the IGFET between the two trapezoidal embedded semiconductor regions 60A.

Due to the constraint on the crystal structure and lattice mismatch, the variety of the material that may be used for the embedded trapezoidal semiconductor region 60A is determined by the crystal structure and the lattice constant of the substrate semiconductor region 10. For example, if the substrate semiconductor region 10 comprises silicon, the embedded semiconductor material may be silicon-germanium alloy, silicon-carbon alloy, or silicon-carbon-germanium alloy. If the semiconductor substrate region 10 comprises gallium arsenide, the embedded semiconductor material may comprise indium-gallium arsenide. Other combinations that are capable of producing epitaxial alignment are known in the art.

Since the substrate semiconductor region 10 is epitaxially aligned to the trapezoidal embedded semiconductor region 60A, each of the facets (50, 51 in FIG. 3) on the substrate semiconductor region 10 adjoins a facet of the embedded semiconductor region 60A that is located directly across the boundary between the trapezoidal embedded semiconductor region 60A and the substrate semiconductor region 10. Therefore, at each boundary between the trapezoidal embedded semiconductor region 60A and the substrate semiconductor region 10, two facets of the same surface orientations, one belonging to the trapezoidal embedded semiconductor region 60A and the other belonging to the semiconductor substrate region 10, are adjoined to each other with an epitaxial alignment across the boundary. At a ridge where two facets belonging to the substrate semiconductor region 10 are adjoined, two other facets belonging to the trapezoidal embedded semiconductor region 60A are also adjoined.

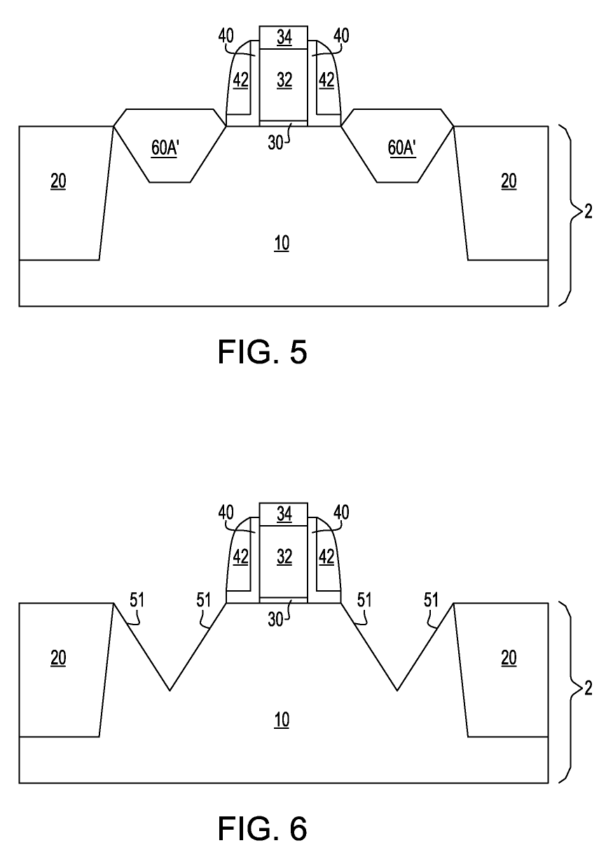

Referring to FIG. 5, a variant of the first exemplary semiconductor structure is shown, wherein the selective epitaxy process is prolonged after the embedded semiconductor region 60A reaches a top surface of the STI 20. Two more facets are added to the cross-sectional area of the embedded semiconductor region 60A. The trapezoidal embedded semiconductor region 60A in FIG. 4 grows into a hexagonal embedded semiconductor region 60A′, i.e., an embedded semiconductor region that has a hexagonal cross-sectional area. Further, it is herein explicitly contemplated that the selective epitaxy process may be terminated before the growth of the embedded semiconductor region reaches the original semiconductor surface 11, resulting in a trapezoidal embedded semiconductor region (not shown) that does not contact the STI 20.

Referring to FIG. 6, a second exemplary structure according to a second embodiment of the present invention is shown. The semiconductor structure in FIG. 6 is formed by extending the crystallographic anisotropic etch after the first exemplary semiconductor structure shown in FIG. 3 is formed. The low etch rate crystallographic facet 51 in FIG. 3 extends further downward until the high etch rate crystallographic facet 50 is reduced to a ridge that joins the two low etch rate crystallographic facets 51. A V-shaped groove with a ridge in the middle is formed by the two low etch rate crystallographic facets 51 in an exposed semiconductor area. Thus, the crystallographic anisotropic etch produces at least one cavity surrounded by crystallographic facets adjoined by a ridge on the substrate semiconductor region 10.

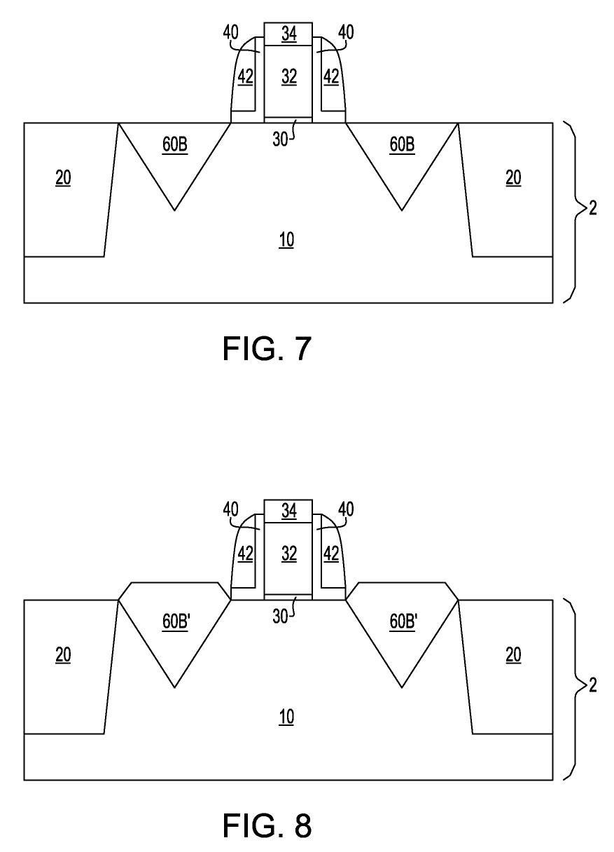

Referring to FIG. 7, an embedded semiconductor material is deposited on the low etch rate crystallographic facets 51 of the substrate semiconductor region 10 preferably by selective epitaxy as in the first embodiment. The requirements for the composition, crystal structure, and lattice constants are the same as in the first embodiment. Preferably, the selective epitaxy process provides a higher growth rate to surfaces that are parallel to the original semiconductor surface 11 than to surfaces that are parallel to the low etch rate crystallographic facets 51. In other words, the selective epitaxy causes the embedded semiconductor material to grow at a higher growth rate from surfaces parallel to the original semiconductor surface 11 in the direction perpendicular to the original semiconductor surface 11 than the growth rate of the embedded semiconductor material from the low etch rate crystallographic facet 51 in the direction perpendicular to the low etch rate crystallographic facets 51. This causes the growth surface of the embedded semiconductor material to be parallel to the original semiconductor surface 11. The embedded semiconductor material thus forms triangular embedded semiconductor regions 60B, i.e., embedded semiconductor regions with a triangular cross-sectional area.

Through the same mechanism as in the first embodiment, the strained embedded semiconductor region 60B exerts stress on neighboring semiconductor structures. Also, the variety of the material that may be used for the embedded triangular semiconductor region 60B is determined by the crystal structure and the lattice constant of the substrate semiconductor region 10.

As in the first embodiment, each of the facets 51 (in FIG. 6) of the substrate semiconductor region 10 adjoins a facet of the triangular embedded semiconductor region 60B that is located directly across the boundary between the trapezoidal embedded semiconductor region 60B and the substrate semiconductor region 10. At a ridge where two facets belonging to the substrate semiconductor region 10 are adjoined, two other facets belonging to the triangular embedded semiconductor region 60B are also adjoined.

Referring to FIG. 8, a variant of the second exemplary semiconductor structure is shown, wherein the selective epitaxy process is prolonged after the embedded semiconductor region 60B reaches a top surface of the STI 20. Two more facets are added to the cross-sectional area of the embedded semiconductor region 60B. The triangular embedded semiconductor region 60B in FIG. 7 grows into a pentagonal embedded semiconductor region 60B′, i.e., an embedded semiconductor region that has a pentagonal cross-sectional area. Further, it is herein explicitly contemplated that the selective epitaxy process may be terminated before the growth of the embedded semiconductor region reaches the original semiconductor surface 11, resulting in a triangular embedded semiconductor region (not shown) that does not contact the STI 20.

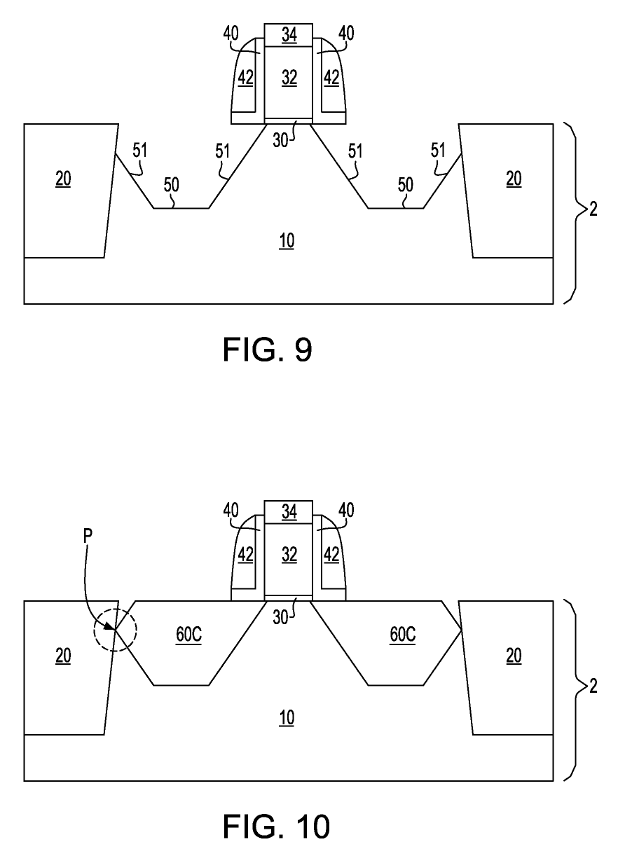

Referring to FIG. 9, a third exemplary structure according to a third embodiment of the present invention is shown. The semiconductor structure in FIG. 8 is formed by subjecting the first exemplary semiconductor structure shown in FIG. 3 to a subsequent isotropic etch. During the isotropic etch, the substrate semiconductor material is removed at substantially the same rate along the various crystallographic orientations of the substrate semiconductor region 10. Preferably, the high etch rate crystallographic facets 50 are parallel to the original semiconductor surface 11. Alternatively, the high etch rate crystallographic facet 50 may not be parallel to the original semiconductor surface 11. The portions of the substrate semiconductor region 10 underneath the spacers (40, 42) are undercut during the isotropic etch. Further, the line at which a low etch rate crystallographic facet 51 adjoins the shallow trench isolation (STI) 20 is recessed downward along a sidewall of the STI 20. The cavity in the structure in FIG. 3 is thus enlarged to enable incorporation of more embedded semiconductor material into the semiconductor structure. Thus, the combination of the crystallographic anisotropic etch and the isotropic etch produces at least one cavity surrounded by crystallographic facets adjoined by two ridges on the substrate semiconductor region 10.

Referring to FIG. 10, an embedded semiconductor material is deposited on the crystallographic facets (50, 51) of the substrate semiconductor region 10 preferably by selective epitaxy as in the first embodiment. The requirements for the composition, crystal structure, and lattice constants are the same as in the first embodiment. Preferably, the selective epitaxy process provides a higher growth rate to surfaces that are parallel to original semiconductor surface 11 than to surfaces that are parallel to the low etch rate crystallographic facets 51. This causes the growth surface of the embedded semiconductor material to be parallel to the original semiconductor surface 11. The growth of the embedded semiconductor material may be pegged, however, at a pegging line P along a sidewall of the shallow trench isolation 20. A facet develops from the pegging line P upward and at an angle from the sidewall on which the pegging liner P is formed. The embedded semiconductor material thus forms pentagonal embedded semiconductor regions 60C, i.e., embedded semiconductor regions with a pentagonal cross-sectional area.

Through the same mechanism as in the first embodiment, the strained embedded semiconductor region 60C exerts stress on neighboring semiconductor structures. Also, the variety of the material that may be used for the embedded pentagonal semiconductor region 60C is determined by the crystal structure and the lattice constant of the substrate semiconductor region 10.

As in the first embodiment, each of the facets 51 (in FIG. 9) of the substrate semiconductor region 10 adjoins a facet of the pentagonal embedded semiconductor region 60C that is located directly across the boundary between the pentagonal embedded semiconductor region 60C and the substrate semiconductor region 10. At a ridge where two facets belonging to the substrate semiconductor region 10 are adjoined, two other facets belonging to the triangular pentagonal embedded semiconductor region 60C are also adjoined.

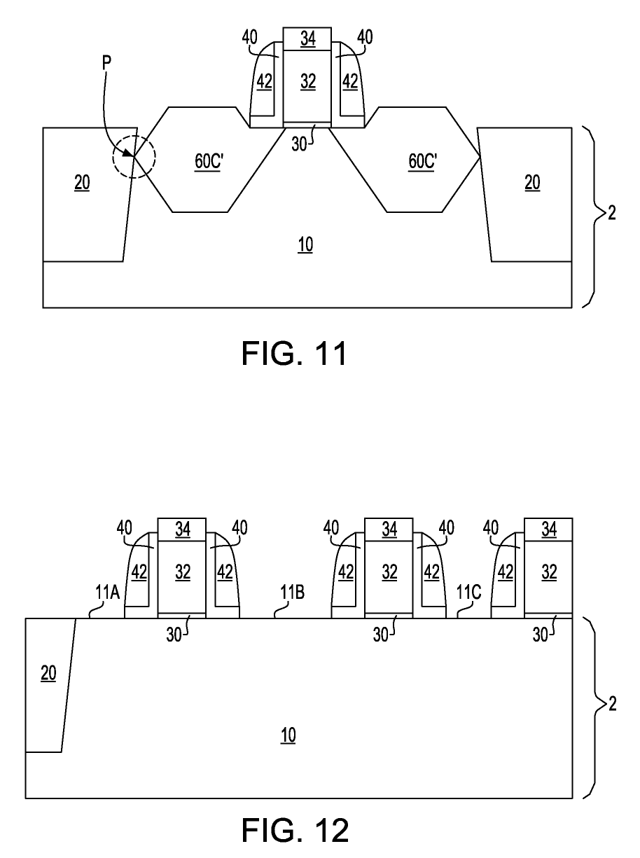

Referring to FIG. 11, a variant of the third exemplary semiconductor structure is shown, wherein the selective epitaxy process is prolonged after the embedded semiconductor region 60C reaches a top surface of the STI 20. Two more facets are added to the cross-sectional area of the embedded semiconductor region 60C. The pentagonal embedded semiconductor region 60C in FIG. 7 grows into a heptagonal embedded semiconductor region 60C′, i.e., an embedded semiconductor region that has a heptagonal cross-sectional area. Further, it is herein explicitly contemplated that the selective epitaxy process may be terminated before the growth of the embedded semiconductor region reaches the original semiconductor surface 11, resulting in a trapezoidal or pentagonal embedded semiconductor region (not shown).

Referring to FIG. 12, a fourth exemplary structure according to a fourth embodiment of the present invention is shown. A first exposed semiconductor surface 11A adjoining shallow trench isolation 20 and second and third exposed semiconductor surfaces (11B and 11C, respectively), each of which adjoin a pair of gate structures, are shown. The distance between the adjoining gate structures is greater for the second exposed semiconductor surface 11B than for the third exposed semiconductor surface 11C.

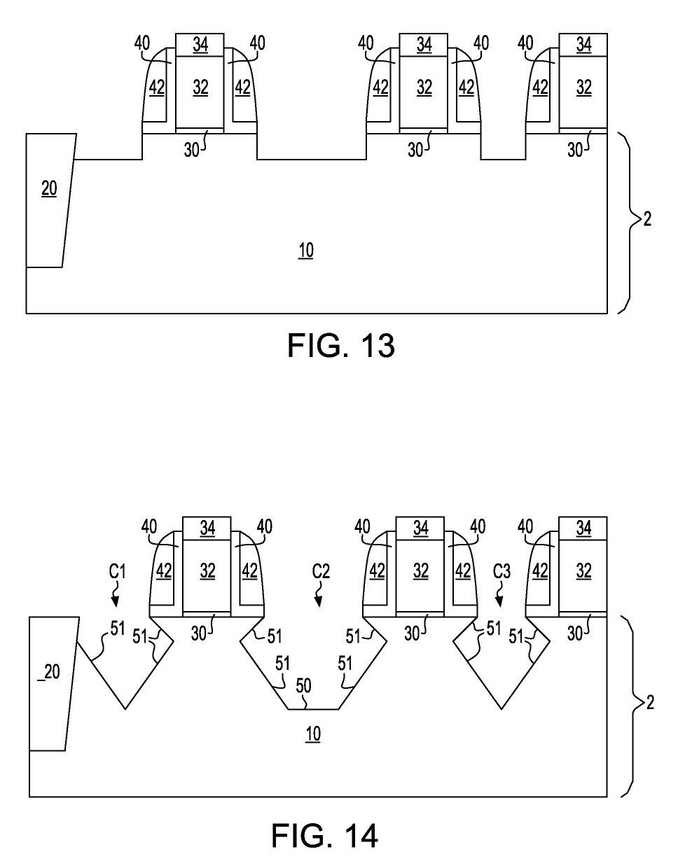

Referring to FIG. 13, the substrate semiconductor region 10 is recessed by a reactive ion etch (RIE). The reactive ion etch is anisotropic and forms substantially vertical sidewalls on the recessed portions of the substrate semiconductor region 10. The depth of the reactive ion etch may be in the range from about 3 nm to about 100 nm, and preferably in the range from about 5 nm to about 20 nm.

Referring to FIG. 14, a crystallographic anisotropic etch performed on the exposed semiconductor surfaces (11A, 11B, 11C) forms both high etch rate crystallographic facets 50 and low etch rate crystallographic facets 51. The substrate semiconductor material is etched fast in the direction perpendicular to the high etch rate crystallographic facets 50, while the low etch rate crystallographic facets 51 tend to grow in size laterally until the they meet another low etch rate crystallographic facet 51. A first, second, and third cavities (C1, C2, C3, respectively) that are surrounded by crystallographic facets are formed underneath each of the three original exposed semiconductor surfaces (11A, 11B, 11C in FIG. 12) by the crystallographic anisotropic etch. Depending on the duration of the crystallographic anisotropic etch, a high etch rate crystallographic facet 50 may or may not be present in a cavity.

For example, the crystallographic anisotropic etch may proceed such that the first cavity C1 comprises three low etch rate crystallographic facets 51 and does not contain a high etch rate crystallographic facet 50. The second cavity C2, formed underneath the second exposed semiconductor surface 11B, comprises one high etch rate crystallographic facet 50 and four low etch rate crystallographic facets 51. The third cavity C3, formed underneath the third exposed semiconductor surface 11C, comprises three low etch rate crystallographic facets 51 and does not contain a high etch rate crystallographic facet 50. It is understood that a high etch rate crystallographic facet 50 may be present in the first and third cavities (C1, C3) if the crystallographic anisotropic etch is shortened.

Some of the crystallographic facets in the fourth embodiment are “retro-facets” that face downward, i.e., crystallographic facets in which a surface normal toward the cavity (C1, C2, or C3) has a downward component. The retro-facets are formed because the crystallographic anisotropic etch is pegged at the edge of the gate spacers (40, 42). At a microscopic level, as individual atoms of the substrate semiconductor region 10 are removed by the crystallographic anisotropic etch, microscopic facets are formed around the edge of the gate spacers (40, 42). While a microscopic facet with a high etch rate is etched during the crystallographic anisotropic etch, a microscopic facet with a low etch rate is locked in its place and grows only laterally as the etch front of an adjacent high etch rate crystallographic facet moves into the substrate semiconductor region 10.

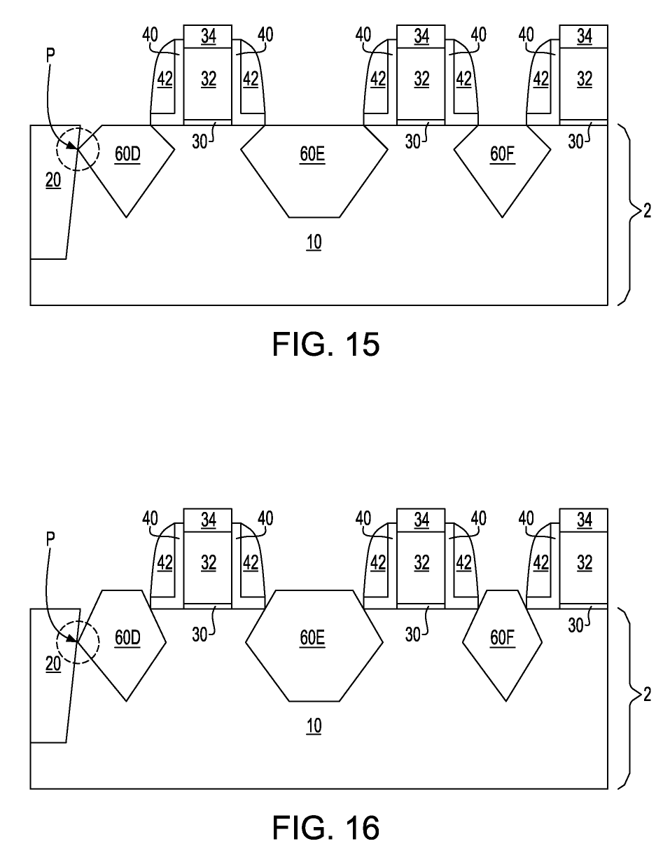

Referring to FIG. 15, an embedded semiconductor material is deposited on the crystallographic facets (50, 51) of the substrate semiconductor region 10 preferably by selective epitaxy as in the first embodiment. The requirements for the composition, crystal structure, and lattice constants are the same as in the first embodiment. Preferably, the selective epitaxy process provides a higher growth rate to surfaces that are parallel to the original semiconductor surface 11 than to surfaces that are parallel to the low etch rate crystallographic facets 51. This causes the growth surface of the embedded semiconductor material to be parallel to the original semiconductor surface 11. The embedded semiconductor material thus forms a first pentagonal embedded semiconductor region 60D in the first cavity C1, a hexagonal embedded semiconductor region 60E in the second cavity C2, and a second pentagonal embedded semiconductor region 60F in the third cavity C3. The pentagonal embedded semiconductor regions (60D, 60F) have a pentagonal cross-sectional area and the hexagonal embedded semiconductor region 60E has a hexagonal cross-sectional area.

Through the same mechanism as in the first embodiment, the strained embedded semiconductor regions (60D, 60E, 60F) exerts stress on neighboring semiconductor structures. Also, the variety of the material that may be used for the embedded triangular semiconductor regions (60D, 60E, 60F) is determined by the crystal structure and the lattice constant of the substrate semiconductor region 10. The strained embedded semiconductor regions may be enclosed by substrate semiconductor regions 10 up to the level of the original semiconductor surface (11B, 11C) as in the case of the hexagonal embedded semiconductor region 60E and the second pentagonal embedded semiconductor region 60F. Alternatively, the strained embedded semiconductor regions may contact the shallow trench isolation 20 at an edge of a crystallographic facet, in which the edge is also a ridge adjoining two crystallographic facets, as is the case with the first pentagonal embedded semiconductor region 60D. The edge forms a pegging line P, which is recessed from the top surface of the STI 20 by a depth on the order of the depth of the recess RIE.

As in the first embodiment, each of the facets 51 (in FIG. 14) of the substrate semiconductor region 10 adjoins a facet of one of the embedded semiconductor regions (60D, 60E, or 60F) that is located directly across the boundary between the embedded semiconductor regions (60D, 60E, or 60F) and the substrate semiconductor region 10. At a ridge where two facets belonging to the substrate semiconductor region 10 are adjoined, two other facets belonging to the same embedded semiconductor regions (60D, 60E, or 60F) are also adjoined.

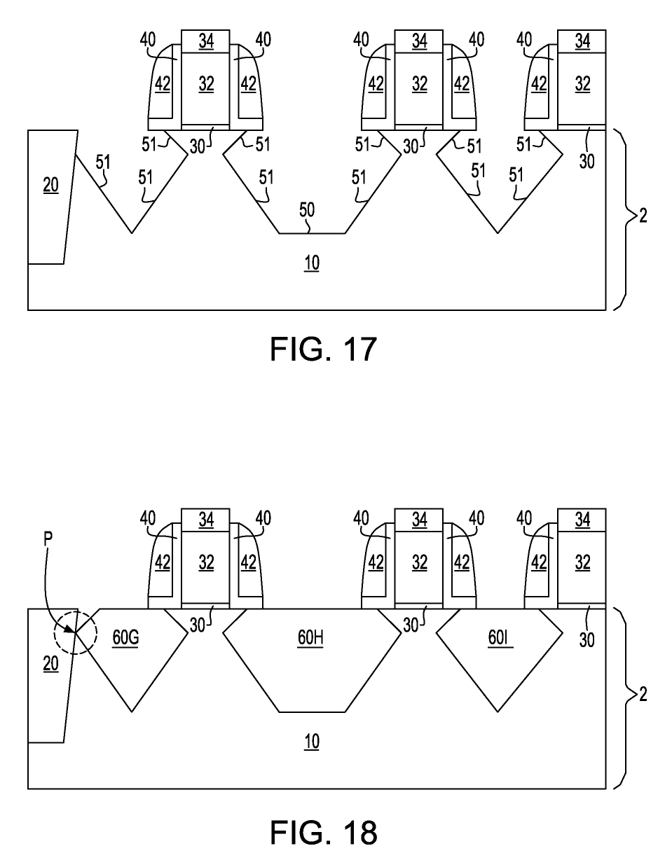

Referring to FIG. 16, a variant of the fourth exemplary semiconductor structure is shown, wherein the selective epitaxy process is prolonged after the embedded semiconductor regions (60D, 60E, 60F) reaches a top surface of the STI 20. More facets are added to the cross-sectional area of the embedded semiconductor regions (60D, 60E, 60F). The additional facets above the level of the original semiconductor surfaces (11A, 11B, 11C) may, or may not, be parallel to the low etch rate crystallographic facets 51. Top surfaces of the embedded semiconductor regions (60D, 60E, 60F) are located above the level of the original semiconductor surfaces (11A, 11B, 11C). Further, it is herein explicitly contemplated that the selective epitaxy process may be terminated before the growth of the embedded semiconductor region reaches the original semiconductor surfaces (11A, 11B, 11C), resulting in a embedded semiconductor region (not shown) with top surfaces located at a level lower than the original semiconductor surfaces (11A, 11B, 11C).

Referring to FIG. 17, a fifth exemplary structure according to a fifth embodiment of the present invention is shown. The semiconductor structure in FIG. 17 is formed by subjecting the fourth exemplary semiconductor structure shown in FIG. 14 to a subsequent isotropic etch. During the isotropic etch, the substrate semiconductor material is removed at substantially the same rate along the various crystallographic orientations of the substrate semiconductor region 10. Preferably, the high etch rate crystallographic facets 50 are parallel to the original semiconductor surface 11. Alternatively, the high etch rate crystallographic facet 50 may not be parallel to the original semiconductor surface 11. The portions of the substrate semiconductor region 10 underneath the spacers (40, 42) are undercut during the isotropic etch. Further, the line at which a low etch rate crystallographic facet 51 adjoins the shallow trench isolation (STI) 20 is recessed downward along a sidewall of the STI 20. The cavity in the structure in FIG. 3 is thus enlarged to enable incorporation of more embedded semiconductor material into the semiconductor structure. The combination of the crystallographic anisotropic etch and the isotropic etch produces enlarges the cavities (C1, C2, C3) of FIG. 14 to subsequently accommodate an increased volume of embedded semiconductor material in the semiconductor substrate 2 according to the fifth embodiment.

Referring to FIG. 18, an embedded semiconductor material is deposited on the crystallographic facets (50, 51) of the substrate semiconductor region 10 preferably by selective epitaxy as in the first embodiment. The requirements for the composition, crystal structure, and lattice constants are the same as in the first embodiment. Preferably, the selective epitaxy process provides a higher growth rate to surfaces that are parallel to original semiconductor surfaces (11A, 11B, 11C) than to surfaces that are parallel to the low etch rate crystallographic facets 51. This causes the growth surface of the embedded semiconductor material to be parallel to the original semiconductor surface 11. The growth of the embedded semiconductor material may be pegged, however, at a pegging line P along a sidewall of the shallow trench isolation 20. A facet develops from the pegging line P upward and at an angle from the sidewall on which the pegging liner P is formed.

The embedded semiconductor material thus forms a first pentagonal embedded semiconductor region 60G in the first enlarged cavity C1, a hexagonal embedded semiconductor region 60H in the second enlarged cavity C2, and a second pentagonal embedded semiconductor region 60I in the third enlarged cavity C3. The pentagonal embedded semiconductor regions (60G, 60I) have a pentagonal cross-sectional area and the hexagonal embedded semiconductor region 60H has a hexagonal cross-sectional area.

Through the same mechanism as in the first embodiment, the strained embedded semiconductor regions (60G, 60H, 60I) exert stress on neighboring semiconductor structures. Also, the variety of the material that may be used for the embedded pentagonal semiconductor regions (60G, 60H, 60I) is determined by the crystal structure and the lattice constant of the substrate semiconductor region 10.

As in the first embodiment, each of the facets 51 (in FIG. 17) of the substrate semiconductor region 10 adjoins a facet of one of the polygonal embedded semiconductor regions (60G, 60H, or 60I) that is located directly across the boundary between the polygonal embedded semiconductor region (60G, 60H, or 60I) and the substrate semiconductor region 10. At a ridge where two facets belonging to the substrate semiconductor region 10 are adjoined, two other facets belonging to the same polygonal embedded semiconductor region (60G, 60H, or 60I) are also adjoined.

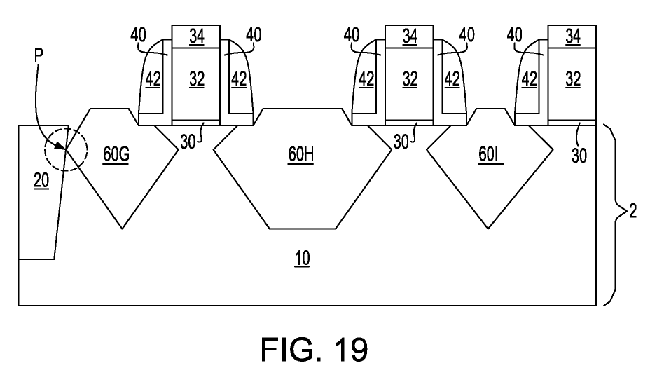

Referring to FIG. 19, a variant of the fifth exemplary semiconductor structure is shown, wherein the selective epitaxy process is prolonged after the embedded semiconductor regions (60G, 60H, 60I) reaches a top surface of the STI 20. More facets are added to the cross-sectional area of the embedded semiconductor regions (60G, 60H, 60I). Further, it is herein explicitly contemplated that the selective epitaxy process may be terminated before the growth of the embedded semiconductor region reaches the original semiconductor surfaces (11A, 11B, 11C), resulting in a embedded semiconductor region (not shown) with top surfaces located at a level lower than the original semiconductor surfaces (11A, 11B, 11C).

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure comprising:
a substrate semiconductor region including a substrate semiconductor material and located within a semiconductor substrate;
at least one embedded semiconductor region including an embedded semiconductor material and located within said semiconductor substrate, wherein said embedded semiconductor material and said semiconductor substrate material have different material compositions; and
at least one boundary where at least two first facets of said substrate semiconductor region adjoin at least two second facets of said at least one embedded semiconductor region, wherein adjoined facets across said boundary have the same crystallographic orientation, and said first facets and said second facets are adjoined by a ridge.

2. The semiconductor structure of claim 1, wherein a vertical cross-section perpendicular to said ridge is a polygon having at least three sides, wherein at least three surfaces of said embedded semiconductor region containing said at least three sides of said polygon are crystallographic surfaces selected from the group consisting of {100}, {110}, {111}, {211}, {221}, {311}, {321}, {331}, and {332}.

3. The semiconductor structure of claim 2, wherein said polygon has at least four sides, and three surfaces of said embedded semiconductor region containing three of said at least four sides directly contact said substrate semiconductor region with epitaxial alignment.

4. The semiconductor structure of claim 3, wherein two surfaces of said embedded semiconductor region containing two parallel sides of said four sides of said polygon comprise a set of two facets having the same orientation as said semiconductor substrate.

5. The semiconductor structure of claim 2, wherein said polygon has at least five sides, and at least three surfaces of said embedded semiconductor region containing at least three of said at least five sides directly contact said substrate semiconductor region with epitaxial alignment.

6. The semiconductor structure of claim 5, wherein a surface of said embedded semiconductor region not adjoining said substrate semiconductor region comprises a facet having the same orientation as said semiconductor substrate.

7. The semiconductor structure of claim 2, wherein said polygon has at least six sides, and at least five surfaces of said embedded semiconductor region containing at least five of said at least six sides directly contact said substrate semiconductor region with epitaxial alignment.

8. The semiconductor structure of claim 7, wherein two surfaces of said embedded semiconductor region containing two of said six sides of said polygon comprise a set of two facets having the same orientation as said semiconductor substrate.

9. The semiconductor structure of claim 2, wherein said polygon has at least three sides, said semiconductor substrate is a (001) orientation substrate, and at least three surfaces of said embedded semiconductor region containing said three sides comprise a (001) facet and a set of two {110} facets.

10. The semiconductor structure of claim 1, wherein said embedded semiconductor region abuts a bottom surface of a gate spacer of an insulated gate field effect transistor (IGFET).

11. The semiconductor structure of claim 1, wherein said substrate semiconductor material and said embedded semiconductor material have the same crystal structure and a lattice mismatch in the range from 0% to about 10%.

12. The semiconductor structure of claim 1, wherein a surface of said at least one embedded semiconductor region adjoins a sidewall surface of shallow trench isolation.

13. A method of manufacturing a semiconductor structure, comprising:
providing a semiconductor substrate having a substrate semiconductor region and at least one exposed semiconductor surface;
subjecting said at least one exposed semiconductor surface to a crystallographic anisotropic etch;
forming at least one cavity with crystallographic facets within said semiconductor substrate; and
forming at least one embedded semiconductor region by filling said at least one cavity with an embedded semiconductor material, wherein said embedded semiconductor material is epitaxially aligned with said substrate semiconductor material.

14. The method of claim 13, further comprising recessing said at least one exposed semiconductor surface with a reactive ion etch prior to forming said at least one cavity.

15. The method of claim 13, further comprising performing an isotropic etch on said at least one cavity of said semiconductor substrate.

16. The method of claim 13, further comprising exposing a bottom surface of a spacer of a insulated gate field effect transistor (IGFET).

17. The method of claim 13, wherein said embedded semiconductor region and said substrate semiconductor region have different material compositions and said embedded semiconductor region applies stress to said substrate semiconductor region.

18. The method of claim 13, further comprising forming at least one boundary where at least two first facets of said substrate semiconductor region adjoin at least two second facets of said at least one embedded semiconductor region, wherein adjoined facets across said boundary have the same crystallographic orientation, and said first facets and said second facets are adjoined by a ridge.

19. The method of claim 18, wherein a vertical cross-section perpendicular to said ridge is a polygon with at least three sides, wherein surfaces of said embedded semiconductor region containing said at least three sides of said polygon are crystallographic surfaces selected from the group consisting of {100}, {110}, {111}, {211}, {221}, {311}, {321}, {331}, and {332}.

20. The method of claim 19, wherein said semiconductor substrate is a (001) orientation silicon substrate and said surfaces of said embedded semiconductor region comprise at least one (001) surface and at least two {110} surfaces.
